(19) United States
(12) Patent Application Publication
(10) Pub. No.: US 2004/0145961 A1
(43) Pub. Date: Jul. 29, 2004

(54) Portable device having a universal unique identifier

(75) Inventors: Show-Nan Chung, Sinjhuang City (TW); Yi-Tyng Lin, Taipei City (TW); Chin-Peng Tsai, Sindian City (TW)

Correspondence Address: BACON & THOMAS, PLLC, 625 SLATERS LANE, FOURTH FLOOR, ALEXANDRIA, VA, 22314

(73) Assignee: Tatung Co., Ltd., Taipei City (TW)

(21) Appl. No.: 10/755,264

(22) Filed: Jan. 13, 2004

(30) Foreign Application Priority Data
Jan. 20, 2003 (TW) 92200991

(51) Int. Cl. G11C 8/02

(52) U.S. Cl. 365/232

(57) ABSTRACT

A portable device having a Universal Unique Identifier comprises a plurality of nonvolatile memory chips and a microprocessor. The nonvolatile memory chips provide a storage space for portable device to store an embedded operation system, and each nonvolatile memory chip has a unique identifier. When the microprocessor receives a UUID reading request from the embedded operation system, a identify code reading driver is executed to read the unique identifier from a specific address of nonvolatile memory so as to reply to the embedded system based on the read unique identifier for producing a UUID.

### BACKGROUND OF THE INVENTION

1. Field of the Invention

The present invention relates to an operation system of Universal Unique Identifiers (UUID), especially to a portable device having a UUID.

2. Description of Related Art

According to the progress of electric technology, each kind of electric device, such as Notebook, computer, Palm and PDA, is getting miniaturized, portable, and powerful in operation capacity, and provides greatest convenience for user. The portable device has a microprocessor to execute embedded operation system in order to identify the UUID. The embedded system will receive a request from UUID to identify the portable device.

In conventional skill, the portable device assembles an ID generator to receive the request from UUID, and provides an UUID for embedded system to identify the operation. Due to the generator, the cost of portable device will increase.

Another method for generating a UUID is writing software to a storage device in portable device when off-line. This method will increase the production cost of portable device because it needs a person assigned to produce, manage and write the UUID. Therefore, it is desirable to improve the conventional UUID operation model to mitigate or obviate the aforementioned problems.

### SUMMARY OF THE INVENTION

The object of the present invention is to provide a portable device having a UUID for preventing the portable device from cost increasing due to use an ID generator and reducing the production cost due to assigning a person to produce, manage and write the UUID.

To achieve the object, there is provided a portable device having a UUID, comprising: a plurality of nonvolatile memory chips for providing a storage space for portable device to store an embedded operation system, each nonvolatile memory chip having an unique identifier; and, a microprocessor executing and controlling the embedded operation system, wherein when the microprocessor receives a UUID reading request from the embedded operation system, a identify code reading driver is executed to read the unique identifier from a specific address of nonvolatile memory so as to reply to the embedded operation system based on the read unique identifier for producing a UUID.

Other objects, advantages, and novel feature of the invention will become more apparent from the following detailed description when taken in conjunction with the accompanying drawings.

### BRIEF DESCRIPTION OF THE DRAWINGS

FIG. 1 shows the structure of embodiment in accordance with the present invention; and

FIG. 2 is a flowchart of embodiment process in accordance with the present invention.

### DETAILED DESCRIPTION OF THE PREFERRED EMBODIMENT

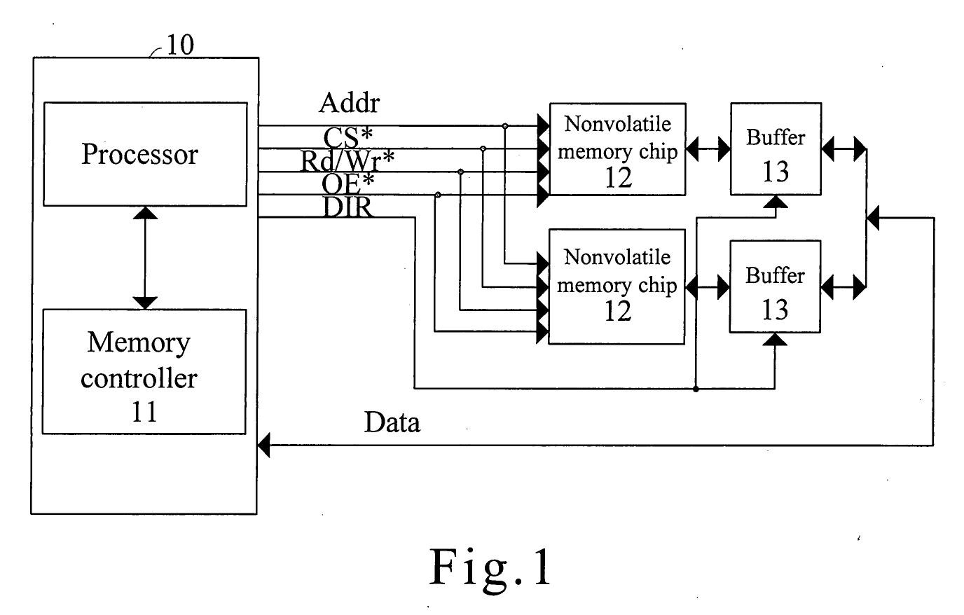

A portable device having a universal unique identifier in accordance with the present invention is illustrated in FIG. 1. The device includes a plurality of nonvolatile memory chips 12 and a microprocessor 10, wherein the flash memory chip 12, such as a NOR pattern, provides a storage space to store an embedded operation system. Each nonvolatile memory chip 12 has a unique ID.

The microprocessor 10 executes and controls the embedded operation system. When it receives a reading UUID request from the embedded operation system, an ID reading driver is started to read a unique ID on specific address from the nonvolatile memory and reply to the embedded operation system for producing a UUID based on the read unique ID.

The UUID is a code with a length of 128 bits, including a 48 bits manufacturer code, a 16 bits version/variant code and a 64 bits device identifier code, wherein, the 48 bits manufacturer code and the 16 bits version/variant code are supplied by an embedded operation system manufacturer. The 64 bits device identifier code is made by the portable device manufacturer. Each portable device needs a 64 bits device identifier code to form a 128 bits Universal Unique Identifier (UUID).

The nonvolatile memory chip 12 is a flash memory and saved with the unique ID at a specific address. The specific address is 0x0000, 0x0001, and 0x0002. When the embedded operation system executes a request for reading UUID, the unique ID on flash memory is used as the 64 bits device identifier code to satisfy the UUID request.

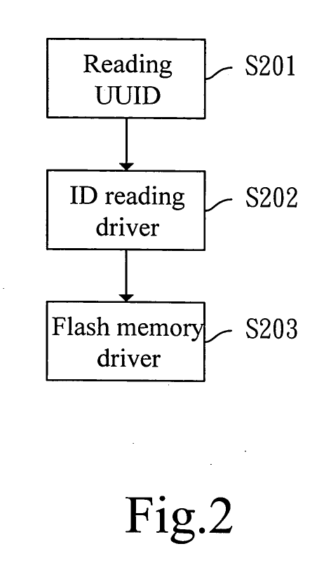

FIG. 2 is a flow chart illustrating that the unique ID on flash memory is used as 64 bits device identifier code according to the invention. In step 201, the embedded operation system executes a request for reading UUID. In step 202, an ID reading driver starts. The ID reading driver will call a flash memory driver to execute a Read Identifier Command. In step 203, a unique ID is read from the flash memory at specific address, so as to reply the embedded operation system request in accordance with read unique ID.

In view of the foregoing, it is known that the present invention is able to use the unique ID on nonvolatile memory chip 12 as the 64 bits device identifier code, so as to prevent the portable device cost rising due to the use of ID generator and to avoid the production cost increasing due to assigning a person to produce, manage and write the UUID.

What is claimed is:

1. A portable device having a universal unique identifier (UUID), comprising:
a plurality of nonvolatile memory chips for providing a storage space for portable device to store an embedded operation system, each nonvolatile memory chip having an unique identifier; and,
a microprocessor executing and controlling the embedded operation system, wherein when the microprocessor receives a UUID reading request from the embedded operation system, a identify code reading driver is executed to read the unique identifier from a specific address of nonvolatile memory so as to reply to the embedded operation system based on the read unique identifier for producing a UUID.

2. The portable device as claimed in claim 1, wherein the UUID has a length of 128 bits and 64 bits of the length are assigned by the embedded operation system.

3. The portable device as claimed in claim 2, wherein the unique ID of the nonvolatile memory has a length of 64 bits.

4. The portable device as claimed in claim 2, wherein the specific address is 0×0000, 0×0001 and 0×0002.

5. The portable device as claimed in claim 2, wherein the nonvolatile is flash memory.
